(19) United States
(12) Patent Application Publication
(10) Pub. No.: US 2024/0283037 A1
(43) Pub. Date: Aug. 22, 2024

(54) BATTERY AND FLEXIBLE PRINTED CIRCUIT BOARD

(71) Applicant: NIPPON MEKTRON, LTD., Tokyo (JP)

(72) Inventors: Kenichi NAKAYAMA, Tokyo (JP); Shuzo YAMADA, Tokyo (JP); Tomoki KANAYAMA, Tokyo (JP)

(73) Assignee: NIPPON MEKTRON, LTD., Tokyo (JP)

(21) Appl. No.: 18/444,608

(22) Filed: Feb. 16, 2024

(30) Foreign Application Priority Data
Feb. 20, 2023 (JP) 2023-024288

(51) Int. Cl. H01M 10/42; H01M 10/48; H05K 1/02; H05K 1/14

(52) U.S. Cl. CPC H01M 10/425; H01M 10/486; H05K 1/028; H05K 1/147; H05K 2201/058; H05K 2201/10037; H05K 2201/10151

(57) ABSTRACT

A battery includes a cell and a flexible printed circuit board to which a temperature measurement element that measures the temperature of the cell is connected. The flexible printed circuit board includes a first flexible printed circuit board portion to which a connector is connected, and a second flexible printed circuit board portion provided through a branch portion branched from the first flexible printed circuit board portion. The first flexible printed circuit board portion is provided with a first temperature measurement element arranged on one surface side of the cell to measure the temperature of one surface of the cell. The second flexible printed circuit board portion is provided with a second temperature measurement element arranged on an other surface side of the cell to measure the temperature of an other surface of the cell.

### CROSS-REFERENCE TO RELATED APPLICATION

This application claims priority from Japanese Patent Application No. 2023-024288 filed with the Japan Patent Office on Feb. 20, 2023, the entire content of which is hereby incorporated by reference.

### BACKGROUND

### 1. Technical Field

The present invention relates to a battery and a flexible printed circuit board.

### 2. Related Art

In a battery such as a secondary battery, the temperature of a cell forming a battery needs to be controlled in some cases, and a technique of arranging a line for temperature measurement inside the battery has been known (see Japanese Patent No. 6047810). The secondary battery includes a cell stack of a plurality of laminated cells in many cases. In a case of a configuration in which a sensor that measures a temperature is provided at a tip end of an electric wire as in the related art, a structure for arranging the sensor inside a battery is generally complicated. For this reason, it is difficult to employ a structure in which the temperatures of both surfaces of a cell are measured, and it is also difficult to arrange sensors at plural locations with favorable accuracy.

### SUMMARY

A battery according to the present invention is a battery including a cell and a flexible printed circuit board to which a temperature measurement element that measures the temperature of the cell is connected. The flexible printed circuit board includes a first flexible printed circuit board portion to which a connector is connected, and a second flexible printed circuit board portion provided through a branch portion branched from the first flexible printed circuit board portion. The first flexible printed circuit board portion is provided with a first temperature measurement element arranged on one surface side of the cell to measure the temperature of one surface of the cell. The second flexible printed circuit board portion is provided with a second temperature measurement element arranged on an other surface side of the cell to measure the temperature of an other surface of the cell.

### BRIEF DESCRIPTION OF THE DRAWINGS

FIG. 1 is a schematic view of the configuration of a battery according to a first embodiment of the present invention;

FIG. 2 is an exploded view of components of a flexible printed circuit board according to the first embodiment of the present invention;

FIGS. 3A and 3B are plan views of the flexible printed circuit board according to the first embodiment of the present invention;

FIGS. 4A and 4B are schematic views of the configuration of the flexible printed circuit board according to the first embodiment of the present invention in a state of the flexible printed circuit board being placed on a cell;

FIGS. 5A and 5B are views for describing a flexible printed circuit board according to a second embodiment of the present invention;

FIGS. 6A and 6B are schematic views of the configuration of the flexible printed circuit board according to the second embodiment of the present invention in a state of the flexible printed circuit board being placed on a cell;

FIGS. 7A and 7B are plan views of a flexible printed circuit board according to a third embodiment of the present invention;

FIGS. 8A and 8B are schematic views of the configuration of the flexible printed circuit board according to the third embodiment of the present invention in a state of the flexible printed circuit board being placed on a cell;

FIGS. 9A and 9B are plan views of a flexible printed circuit board according to a fourth embodiment of the present invention;

FIG. 10 is a schematic view of the configuration of the flexible printed circuit board according to the fourth embodiment of the present invention in a state of the flexible printed circuit board being placed on a cell;

FIG. 11 is an exploded view of components of a flexible printed circuit board according to a fifth embodiment of the present invention; and

FIGS. 12A and 12B are views for describing the flexible printed circuit board according to the fifth embodiment of the present invention.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

An object of the present invention is to provide a battery and a flexible printed circuit board configured so that a structure for arranging a temperature measurement element that measures the temperature of a cell can be simplified.

The present invention employs the following techniques in order to solve the above-described problems.

That is, the battery of the present invention is a battery including a cell, and a flexible printed circuit board to which a temperature measurement element that measures the temperature of the cell is connected, in which the flexible printed circuit board includes a first flexible printed circuit board portion to which a connector is connected, and a second flexible printed circuit board portion provided through a branch portion branched from the first flexible printed circuit board portion, the first flexible printed circuit board portion is provided with a first temperature measurement element arranged on one surface side of the cell to measure the temperature of one surface of the cell, and the second flexible printed circuit board portion is provided with a second temperature measurement element arranged on an other surface side of the cell to measure the temperature of an other surface of the cell.

The flexible printed circuit board of the present invention is a flexible printed circuit board to which a temperature measurement element that measures the temperature of a cell forming a battery is connected, which includes a first flexible printed circuit board portion to which a connector is connected, and a second flexible printed circuit board portion provided through a branch portion branched from the first flexible printed circuit board portion, the first flexible printed circuit board portion being provided with a first temperature measurement element arranged on one surface side of the cell to measure the temperature of one surface of the cell, and the second flexible printed circuit board portion being provided with a second temperature measurement element arranged on an other surface side of the cell to measure the temperature of an other surface of the cell.

According to these aspects of the invention, the first flexible printed circuit board portion and the second flexible printed circuit board portion are arranged so as to sandwich the cell so that the temperature measurement element can be arranged at a desired location for the cell. Moreover, the first flexible printed circuit board portion and the second flexible printed circuit board portion are connected to each other through the branch portion, and therefore, a positional relationship between the first temperature measurement element and the second temperature measurement element is set and arrangement accuracy is also enhanced. Even in a case of application to a cell stack of a plurality of laminated cells, a structure for arranging a temperature measurement element between the cells can be simplified as compared to a case of using a wire-shaped line.

The first flexible printed circuit board portion may have a linear first body portion, and the second flexible printed circuit board portion may have a linear second body portion, the branch portion may be folded 180°, so that the first body portion and the second body portion may be connected to each other through the branch portion, and the first temperature measurement element may be arranged on the one surface side of the cell and the second temperature measurement element may be arranged on the other surface side of the cell.

The first flexible printed circuit board portion and the second flexible printed circuit board portion are arranged so as to sandwich the cell with the branch portion folded 180°, so that the temperature measurement element can be arranged at the desired location relative to the cell. Moreover, the positional relationship between the first temperature measurement element and the second temperature measurement element can be easily set.

The first flexible printed circuit board portion may have a linear first body portion, and the second flexible printed circuit board portion may have a linear second body portion, the first body portion and the second body portion may be connected to each other through the branch portion, and the branch portion may be bent to form a step between the first flexible printed circuit board portion and the second flexible printed circuit board portion, so that the first temperature measurement element may be arranged on the one surface side of the cell and the second temperature measurement element may be arranged on the other surface side of the cell.

The first flexible printed circuit board portion and the second flexible printed circuit board portion are arranged so as to sandwich the cell in such a manner that the step is formed between the first flexible printed circuit board portion and the second flexible printed circuit board portion by bending of the branch portion, and therefore, the temperature measurement element can be arranged at a desired location relative to the cell. Moreover, the positional relationship between the first temperature measurement element and the second temperature measurement element can be easily set.

The first flexible printed circuit board portion may have a first branch portion branched from the first body portion and joined to the first body portion, and the second flexible printed circuit board portion may have a second branch portion branched from the second body portion and joined to the second body portion.

The first branch portion may include a plurality of linear first-branch-portion forming portions, and the second branch portion may include a plurality of linear second-branch-portion forming portions.

The first branch portion may include a single linear first-branch-portion forming portion, and the first-branch-portion forming portion may be arranged with folded 180° at least at one location, and the second branch portion may include a single linear second-branch-portion forming portion, and the second-branch-portion forming portion may be arranged with folded 180° at least at one location.

Electric lines three-dimensionally intersect with each other while keeping insulation from each other at least at a joint portion between the first body portion and the first branch portion and a joint portion between the second body portion and the second branch portion, so that a first ground line for the first temperature measurement element and a second ground line for the second temperature measurement element may be joined into one ground line at least at a portion of the first flexible printed circuit board portion connected to the connector.

With these configurations, the number of poles of the connector can be reduced.

Note that the above-described configurations may be employed in combination to an extent possible.

As described above, according to the present invention, the structure for arranging the temperature measurement element that measures the temperature of the cell can be simplified.

Hereinafter, exemplary embodiments for implementing the present invention will be described in detail based on embodiments with reference to the drawings. Note that unless otherwise specified, the technical scope of the present disclosure is not intended to be limited to the dimensions, materials, shapes, relative arrangements, etc. of components described in the embodiments.

### First Embodiment

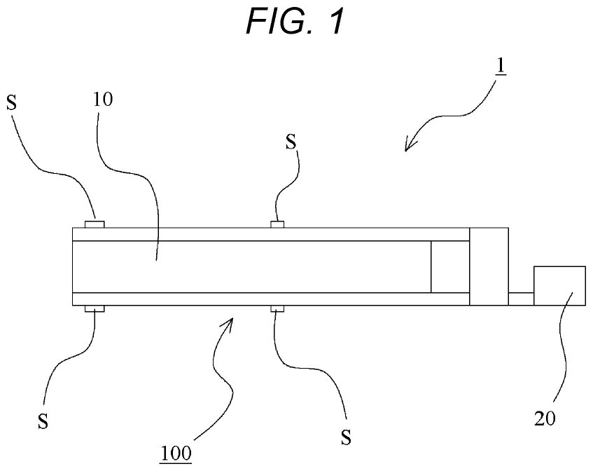

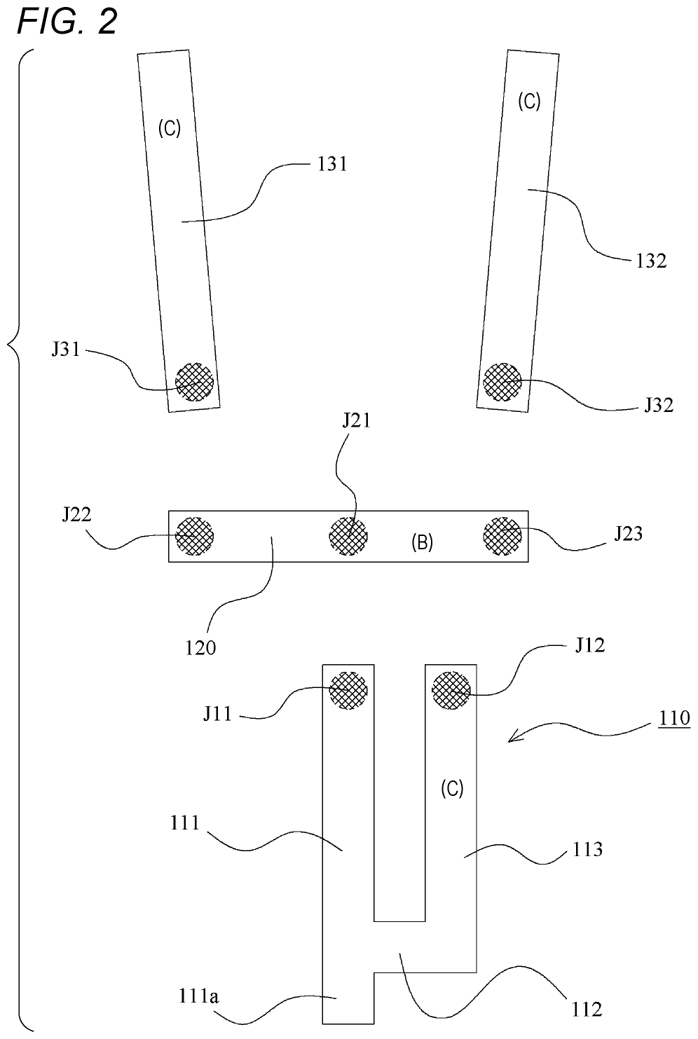

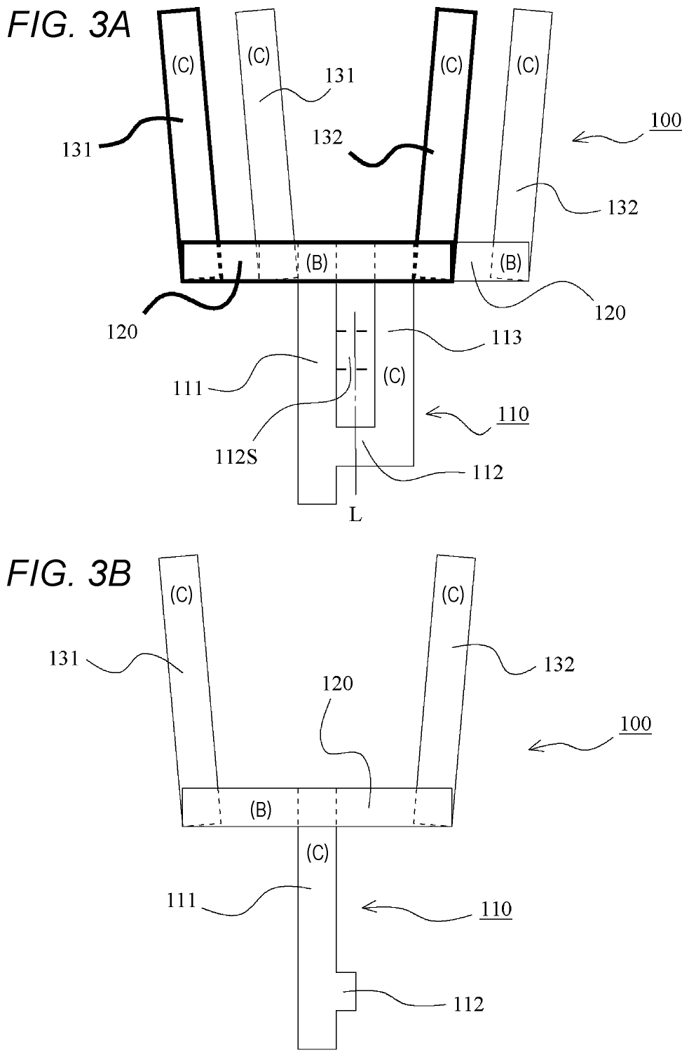

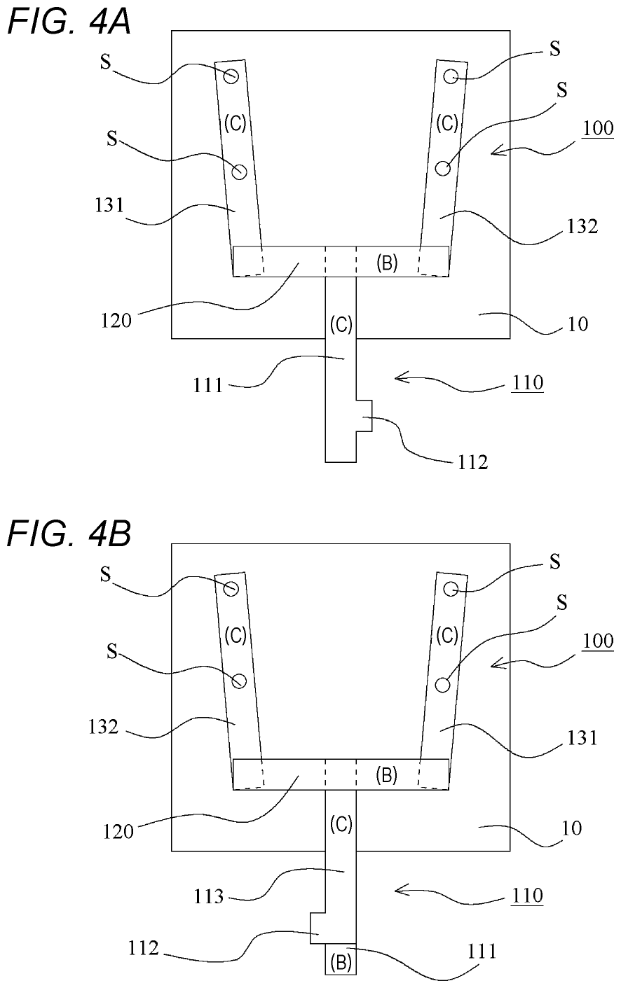

A battery and a flexible printed circuit board (hereinafter referred to as an “FPC”) according to a first embodiment of the present invention will be described with reference to FIGS. 1 to 4B. FIG. 1 is a schematic view of the configuration of the battery according to the first embodiment of the present invention, and simply shows the battery from the side. FIG. 2 is an exploded view of components of the FPC according to the first embodiment of the present invention. FIGS. 3A and 3B are plan views of the FPC according to the first embodiment of the present invention, FIG. 3A showing a state before folding and FIG. 3B showing a state after folding. FIGS. 4A and 4B are schematic views of the configuration of the FPC according to the first embodiment of the present invention in a state of the FPC being placed on a cell, FIG. 4A showing a view of one surface and FIG. 4B showing a view of the other surface.

An FPC 100 according to the present embodiment is formed in such a manner that a plurality of FPCs is joined to each other, and each of the plurality of FPCs is a so-called single-sided FPC. Since a well-known technique is applied to the single-sided FPC, detailed description thereof will be omitted, but the single-sided FPC includes a base film, a line formed on the base film and made of metal foil (normally copper foil), and a cover film provided such that the line is sandwiched between the base film and the cover film. Generally, the single-sided FPC is obtained in such a manner that using a material including the base film and the copper foil provided on the base film, a desired line (circuit) is formed by melting part of the copper foil by etching and the cover film is subsequently bonded thereto. For the sake of convenience in FIGS. 2 to 4B, (B) is assigned in a case where the base film is shown on the front side of the figures, and (C) is assigned in a case where the cover film is shown on the front side of the figures.

### <Battery>

One example of a battery 1 to which the FPC 100 according to the present embodiment is applied will be described with reference to FIG. 1. The battery 1 includes a cell 10 and the FPC 100 to which a temperature measurement element S that measures the temperature of the cell 10 is connected. A connector 20 is attached to one end of the FPC 100. The connector 20 is connected to a control device (not shown) that controls a secondary battery, such as a battery management system. Note that in the present embodiment, only one cell is shown, but generally, the battery includes a cell stack of a plurality of laminated cells. FIG. 1 can be taken as a view focusing on one cell of the cell stack. Note that the present invention can be applied not only to a battery including only one cell, but also to a battery including a cell stack. In the case of the cell stack, it can also be configured such that the temperatures of some or all of a plurality of cells are measured. As the temperature measurement element S, various well-known techniques such as a thermistor, an RTD, and a thermocouple can be employed.

<FPC>

The FPC 100 according to the present embodiment includes a connector-side FPC 110, two linear intermediate FPCs 120, and linear end-side FPCs 131, 132 provided two each (four in total). Note that in FIG. 2, only one intermediate FPC 120, one end-side FPC 131, and one end-side FPC 132 are shown.

The connector-side FPC 110 has a linear first body portion 111, a linear second body portion 113, and a branch portion 112 connecting the first body portion 111 and the second body portion 113 to each other. It can be said that the second body portion 113 is provided through the branch portion 112 branched from the first body portion 111. Note that the connector 20 is mounted on an end portion 111a of the first body portion 111.

In FIG. 2, the vicinity of a region J11 of the first body portion 111 and the back side of the vicinity of a region J21 of the intermediate FPC 120 are joined to each other. Note that joint between the FPCs means that portions of the metal foil (line) exposed without part of the cover film are joined to each other with, e.g., solder. The same also applies hereinafter. Moreover, in FIG. 2, the back side of the vicinity of a region J22 of the intermediate FPC 120 and the vicinity of a region J31 of the end-side FPC 131 are joined to each other, and the back side of the vicinity of a region J23 of the intermediate FPC 120 and the vicinity of a region J32 of the end-side FPC 132 are joined to each other. The intermediate FPC 120 joined to the first body portion 111 and the end-side FPCs 131, 132 joined to the intermediate FPC 120 can be taken as a first branch portion branched from the first body portion 111 and joined to the first body portion 111. Moreover, each of the intermediate FPC 120 and the end-side FPCs 131, 132 forming the first branch portion can be taken as a first-branch-portion forming portion.

The first body portion 111 and the first branch portion (intermediate FPC 120 and end-side FPCs 131, 132) joined to the first body portion 111 form a first flexible printed circuit board portion (hereinafter referred to as a “first FPC portion”). In other words, the first FPC portion has the first body portion 111 and the first branch portion branched from the first body portion 111. Moreover, the first branch portion includes the plurality of first-branch-portion forming portions (intermediate FPC 120 and end-side FPCs 131, 132) joined to each other.

In FIG. 2, the vicinity of a region J12 of the second body portion 113 and the back side of the vicinity of the region J21 of the intermediate FPC 120 are joined to each other. Moreover, in FIG. 2, the back side of the vicinity of the region J22 of the intermediate FPC 120 and the vicinity of the region J31 of the end-side FPC 131 are joined to each other, and the back side of the vicinity of the region J23 of the intermediate FPC 120 and the vicinity of the region J32 of the end-side FPC 132 are joined to each other. The intermediate FPC 120 joined to the second body portion 113 and the end-side FPCs 131, 132 joined to the intermediate FPC 120 can be taken as a second branch portion branched from the second body portion 113 and joined to the second body portion 113. Moreover, each of the intermediate FPC 120 and the end-side FPCs 131, 132 forming the second branch portion can be taken as a second-branch-portion forming portion.

The second body portion 113 and the second branch portion (intermediate FPC 120 and end-side FPCs 131, 132) joined to the second body portion 113 form a second flexible printed circuit board portion (hereinafter referred to as a “second FPC portion”). In other words, the second FPC portion has the second body portion 113 and the second branch portion branched from the second body portion 113. Moreover, the second branch portion includes the plurality of second-branch-portion forming portions (intermediate FPC 120 and end-side FPCs 131, 132) joined to each other.

As described above, the FPC 100 according to the present embodiment includes the first FPC portion to which the connector 20 is connected and the second FPC portion provided through the branch portion 112 branched from the first FPC portion. Moreover, in the present embodiment, the branch portion 112 is folded 180° (see a folding line L in FIG. 3A), and in this manner, the first FPC portion is arranged on one surface side of the cell 10 (see FIG. 4A), and the second FPC portion is arranged on the other surface side of the cell 10 (see FIG. 4B). Note that FIG. 3A shows the state before the branch portion 112 is folded and FIG. 3B shows the state after the branch portion 112 has been folded. As shown in FIG. 3B, in the present embodiment, it is configured such that the first FPC portion and the second FPC portion overlap with each other by folding of the branch portion 112. The FPC 100 is arranged on the cell 10 with the cell 10 sandwiched between the first FPC portion and the second FPC portion.

The first FPC portion is provided with the temperature measurement element (first temperature measurement element) S that measures the temperature of one surface of the cell 10, and the second FPC portion is provided with the temperature measurement element (second temperature measurement element) S that measures the temperature of the other surface of the cell 10. In the present embodiment, the temperature measurement elements S are provided at two locations for each of the end-side FPCs 131, 132, but the number of temperature measurement elements S and arrangement thereof can be set as necessary according to, e.g., the dimensions and shape of the cell 10 and use environment thereof. Moreover, in the present embodiment, it is configured such that the temperature measurement element S that measures the temperature of the other surface of the cell 10 is arranged at a position immediately in the back of each temperature measurement element S that measures the temperature of the one surface of the cell 10.

As described above, in the present embodiment, the branch portion 112 is folded 180°, so that the first temperature measurement element is arranged on the one surface side of the cell 10 and the second temperature measurement element is arranged on the other surface side of the cell 10.

### <Advantages of Battery and FPC According to Present Embodiment>

According to the present embodiment, the first FPC portion and the second FPC portion are arranged so as to sandwich the cell 10, so that the temperature measurement element S can be arranged at a desired location relative to the cell 10. The first FPC portion and the second FPC portion are connected to each other through the branch portion 112, and therefore, a positional relationship between the first temperature measurement element and the second temperature measurement element is set and arrangement accuracy is also enhanced. Even in a case of application to a cell stack of a plurality of laminated cells 10, a structure for arranging a temperature measurement element S between the cells can be simplified as compared to a case of using a wire-shaped line. Moreover, in the present embodiment, the temperatures of both surfaces of the cell 10 can be measured using one connector, and therefore, the number of connectors can be reduced, the structure can be simplified, and a cost can be reduced. Further, in the present embodiment, any of the intermediate FPC 120 and the end-side FPCs 131, 132 are the linear FPC, and therefore, a waste material can be reduced.

In the present embodiment, the first FPC portion and the second FPC portion are arranged so as to sandwich the cell 10 with the branch portion 112 folded 180°, so that the temperature measurement element S can be arranged at a desired location relative to the cell 10. Moreover, the positional relationship between the first temperature measurement element and the second temperature measurement element can be easily set.

As described above, according to the present embodiment, the structure for arranging the temperature measurement element S that measures the temperature of the cell 10 can be simplified. Note that in the present embodiment, the configuration in which the branch portion 112 is provided at only one location has been described, but a configuration in which branch portions 112 are provided at plural locations can also be employed. For example, a branch portion 112S indicated by a dashed line in FIG. 3A can be further provided. The branch portions are provided at the plural locations in this manner so that strength can be enhanced.

Here, a portion of the metal foil (line) is exposed without part of the cover film, and the connector 20 is mounted on the exposed portion. In the case of the present embodiment, even if the single-sided FPC is employed, the cover film of the connector-side FPC 110 is arranged on the front side on both sides of the cell 10. Thus, the connector 20 can be mounted on any of both sides of the cell. As a result, the degree of freedom in a direction of mounting the connector 20 is high.

The arrangement configurations of the first branch portion and the second branch portion are not limited to those of the shown example, and various arrangement configurations can be employed and the temperature measurement element can be arranged at the desired position. Thus, the degree of freedom in design is high.

Note that in the present embodiment, the configuration in which the temperature measurement element S is connected on the side opposite to the cell 10 through, e.g., the base film of the FPC has been described. Note that as long as there is no quality problem, the temperature measurement element S can be arranged in contact with the cell 10. Generally, in a case of employing the configuration in which the temperature measurement element contacts the cell, a probability of the temperature measurement element being damaged due to an increase in a load on the temperature measurement element is high, and for this reason, the temperature measurement element is arranged so as not to directly contact the cell in many cases.

### Second Embodiment

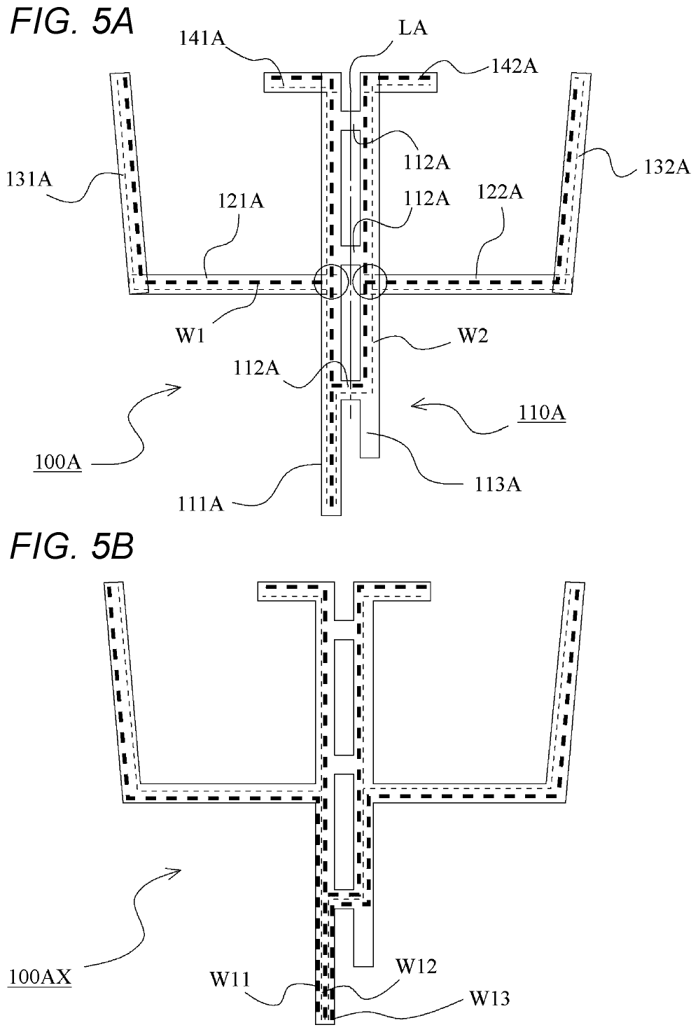

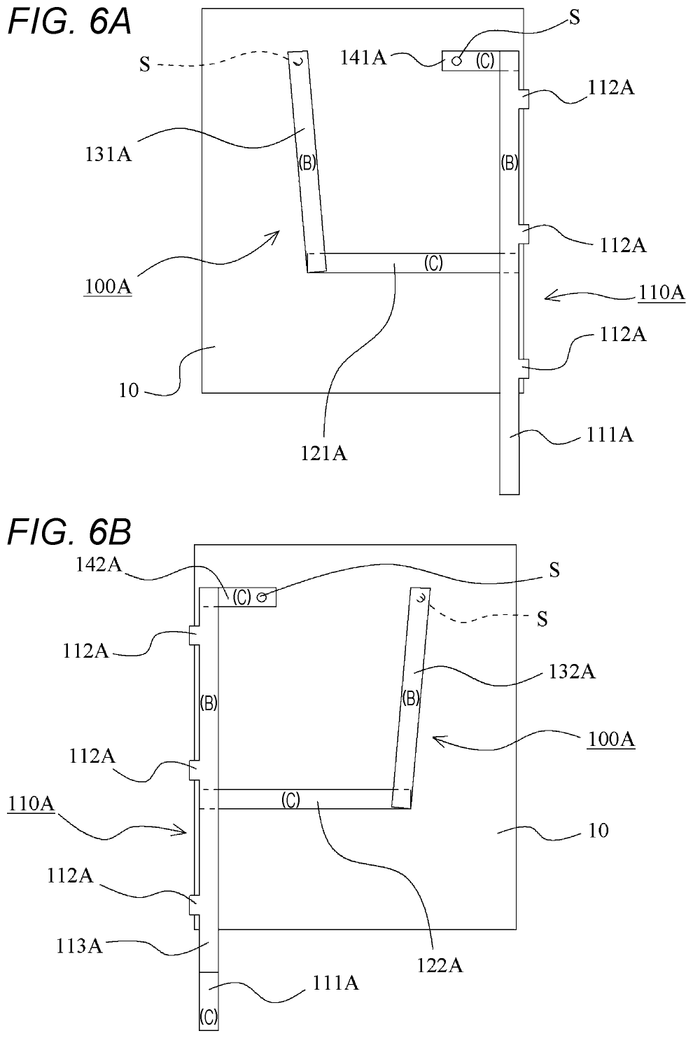

FIGS. 5A, 5B, 6A, and 6B show a second embodiment of the present invention. FIGS. 5A and 5B are views for describing an FPC according to the second embodiment of the present invention, FIG. 5A being a plan view of the FPC according to the second embodiment and FIG. 5B being a plan view of an FPC according to a comparative example. FIGS. 6A and 6B are schematic views of the configuration of the FPC according to the second embodiment of the present invention in a state of the FPC being placed on a cell, FIG. 6A being a view of one surface and FIG. 6B being a view of the other surface.

As in the first embodiment, an FPC 100A according to the present embodiment is also formed in such a manner that a plurality of FPCs is joined to each other, and each of the plurality of FPCs is a so-called single-sided FPC. For the sake of convenience in FIGS. 6A and 6B, (B) is assigned in a case where a base film is shown on the front side of the figures, and (C) is assigned in a case where a cover film is shown on the front side of the figures.

A battery to which the FPC 100A according to the present embodiment is applied is similar to that of the first embodiment, and therefore, description thereof will be omitted.

The FPC 100A according to the present embodiment includes a connector-side FPC 110A, two linear intermediate FPCs 121A, 122A, and four linear end-side FPCs 131A, 132A, 141A, 142A.

The connector-side FPC 110A has a linear first body portion 111A, a linear second body portion 113A, and a branch portion 112A connecting the first body portion 111A and the second body portion 113A to each other. It can be said that the second body portion 113A is provided through the branch portion 112A branched from the first body portion 111A.

As shown in FIGS. 5A, 5B, 6A, and 6B, the first body portion 111A and the intermediate FPC 121A are joined to each other, the intermediate FPC 121A and the end-side FPC 131A are joined to each other, and the first body portion 111A and the end-side FPC 141A are joined to each other. The intermediate FPC 121A joined to the first body portion 111A, the end-side FPC 131A joined to the intermediate FPC 121A, and the end-side FPC 141A can be taken as a first branch portion branched from the first body portion 111A and joined to the first body portion 111A. Moreover, each of the intermediate FPC 121A and the end-side FPCs 131A, 141A forming the first branch portion can be taken as a first-branch-portion forming portion.

The first body portion 111A and the first branch portion (intermediate FPC 121A and end-side FPCs 131A, 141A) joined to the first body portion 111A form a first flexible printed circuit board portion (hereinafter referred to as a “first FPC portion”). In other words, the first FPC portion has the first body portion 111A and the first branch portion branched from the first body portion 111A. Moreover, the first branch portion includes the plurality of first-branch-portion forming portions (intermediate FPC 121A and end-side FPCs 131A, 141A).

As shown in FIGS. 5A, 5B, 6A, and 6B, the second body portion 113A and the intermediate FPC 122A are joined to each other, the intermediate FPC 122A and the end-side FPC 132A are joined to each other, and the second body portion 113A and the end-side FPC 142A are joined to each other. The intermediate FPC 122A joined to the second body portion 113A, the end-side FPC 132A joined to the intermediate FPC 122A, and the end-side FPC 142A can be taken as a second branch portion branched from the second body portion 113A and joined to the second body portion 113A. Moreover, each of the intermediate FPC 122A and the end-side FPCs 132A, 142A forming the second branch portion can be taken as a second-branch-portion forming portion.

The second body portion 113A and the second branch portion (intermediate FPC 122A and end-side FPCs 132A, 142A) joined to the second body portion 113A form a second flexible printed circuit board portion (hereinafter referred to as a “second FPC portion”). In other words, the second FPC portion has the second body portion 113A and the second branch portion branched from the second body portion 113A. Moreover, the second branch portion includes the plurality of second-branch-portion forming portions (intermediate FPC 122A and end-side FPCs 132A, 142A).

As described above, the FPC 100A according to the present embodiment includes the first FPC portion to which a connector 20 is connected and the second FPC portion provided through the branch portion 112A branched from the first FPC portion. Moreover, in the present embodiment, the branch portion 112A is folded 180° (see a folding line LA in FIG. 5A), so that the first FPC portion is arranged on one surface side of a cell 10 (see FIG. 6A), and the second FPC portion is arranged on an other surface side of the cell 10 (see FIG. 6B). Note that in the present embodiment, it is also configured such that the first FPC portion and the second FPC portion overlap with each other by folding of the branch portion 112A. The FPC 100A is arranged on the cell 10 with the cell 10 sandwiched between the first FPC portion and the second FPC portion.

The first FPC portion is provided with a temperature measurement element (first temperature measurement element) S that measures the temperature of one surface of the cell 10, and the second FPC portion is provided with a temperature measurement element (second temperature measurement element) S that measures the temperature of the other surface of the cell 10. In the present embodiment, the temperature measurement element S is provided at one location for each of the end-side FPCs 131A, 141A, 132A, 142A, but the number of temperature measurement elements S and arrangement thereof can be set as necessary according to, e.g., the dimensions and shape of the cell 10 and use environment thereof. Moreover, in the present embodiment, it is also configured such that the temperature measurement element S that measures the temperature of the other surface of the cell 10 is arranged at a position immediately in the back of each temperature measurement element S that measures the temperature of the one surface of the cell 10.

As described above, in the present embodiment, the branch portion 112A is folded 180°, so that the first temperature measurement element is arranged on the one surface side of the cell 10 and the second temperature measurement element is arranged on the other surface side of the cell 10. Note that in the present embodiment, the branch portions 112A are provided at three locations so that strength can be enhanced.

In the FPC 100A of the present embodiment configured as described above, advantageous effects similar to those of the first embodiment can be obtained. Here, in the present embodiment, a wiring circuit is designed such that the number of poles of the connector is reduced. This point will be described with reference to FIGS. 5A and 5B.

Two lines of a ground line and a positive line need to be connected to the temperature measurement element S. If an FPC having the same shape as that of the FPC 100A according to the present embodiment and provided with four temperature measurement elements in total at the same positions as those of the FPC 100A includes one FPC 100AX, arrangement of the ground line and the positive line is as shown in FIG. 5B, for example. Note that in the figure, a thick dashed line is the ground line and a thin dashed line is the positive line. As shown in the figure, three ground lines and two positive lines are present at a position to which the connector is connected, and a five-pole connector is required at minimum.

On the other hand, the present embodiment employs a configuration in which electric lines three-dimensionally intersect with each other while keeping insulation from each other at the joint portion between the first body portion 111A and the first branch portion (here, intermediate FPC 121A) and the joint portion between the second body portion 113A and the second branch portion (here, intermediate FPC 122A) (see portions surrounded by circles in FIG. 5A). With this configuration, a first ground line for the first temperature measurement element and a second ground line for the second temperature measurement element are joined into one ground line at least at a portion (end portion of the first body portion 111A) of the first FPC portion connected to the connector. Thus, in the present embodiment, one ground line and two positive lines are present at the position to which the connector is connected, and a three-pole connector is only required at minimum. Note that the details of the wiring circuit have not been described in the first embodiment, but the number of poles of the connector can also be reduced in the first embodiment because electric lines can three-dimensionally intersect with each other while keeping insulation from each other at the position at which the FPCs are joined to each other.

### Third Embodiment

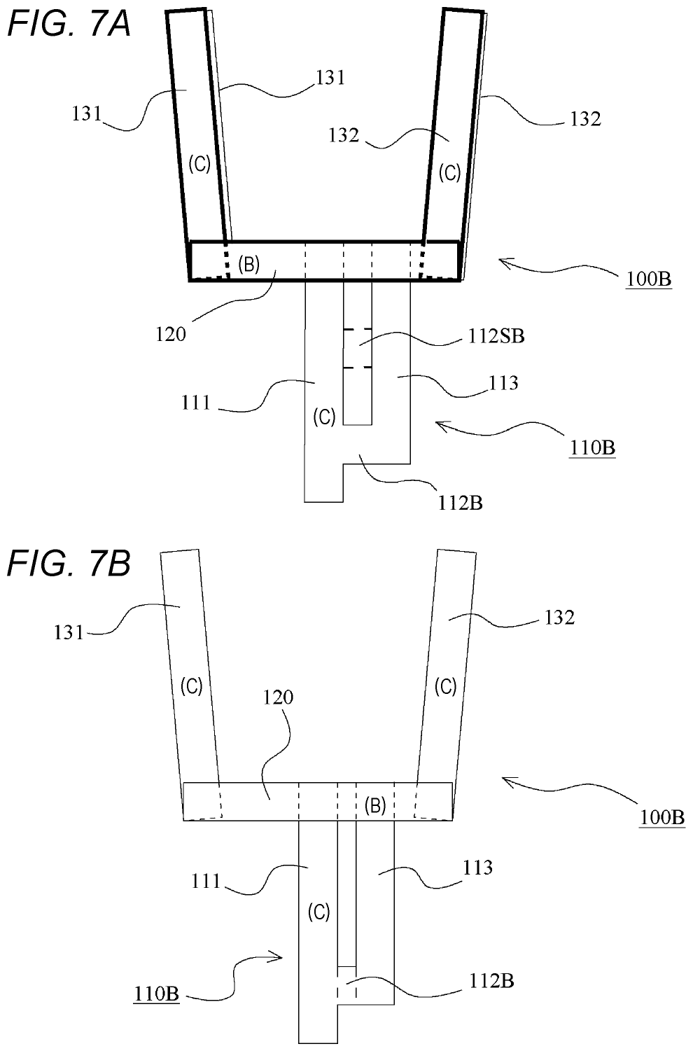

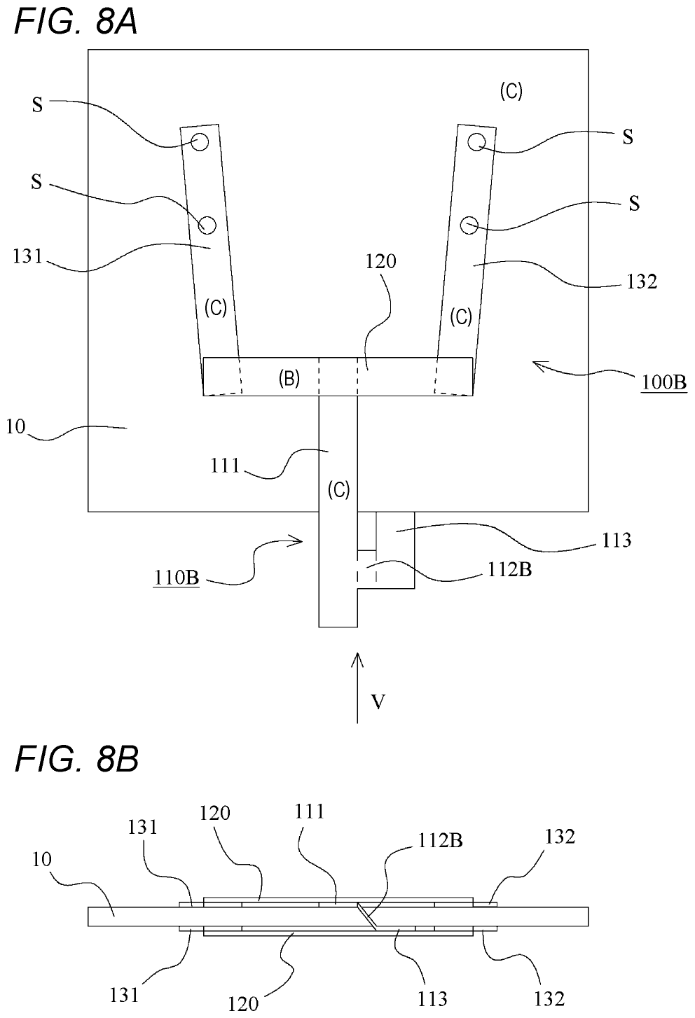

FIGS. 7A, 7B, 8A, and 8B show a third embodiment of the present invention. FIGS. 7A and 7B are plan views of an FPC according to the third embodiment of the present invention, FIG. 7A showing a state before bending of a branch portion and FIG. 7B showing a state after bending of the branch portion. FIGS. 8A and 8B are schematic views of the configuration of the FPC according to the third embodiment of the present invention in a state of the FPC being placed on a cell, FIG. 8A being a plan view and FIG. 8B being a view from a V-direction in FIG. 8A.

The branch portion is folded 180° in the above-described first embodiment, and on the other hand, the present embodiment is different in that the branch portion is bent. A basic configuration of each member is the same as that of the first embodiment, and therefore, the same reference numerals are used to represent the same components as those of the first embodiment and description thereof will be omitted as necessary.

An FPC 100B according to the present embodiment is also formed in such a manner that a plurality of FPCs is joined to each other, and each of the plurality of FPCs is a so-called single-sided FPC. For the sake of convenience in FIGS. 7A, 7B, 8A, and 8B, (B) is assigned in a case where a base film is shown on the front side of the figures, and (C) is assigned in a case where a cover film is shown on the front side of the figures.

A battery to which the FPC 100B according to the present embodiment is applied is similar to that of the first embodiment, and therefore, description thereof will be omitted.

As in the first embodiment, the FPC 100B according to the present embodiment also includes a connector-side FPC 110B, two linear intermediate FPCs 120, and linear end-side FPCs 131, 132 provided two each (four in total).

The connector-side FPC 110B has a linear first body portion 111, a linear second body portion 113, and a branch portion 112B connecting the first body portion 111 and the second body portion 113 to each other. It can be said that the second body portion 113 is provided through the branch portion 112B branched from the first body portion 111.

Joint between the FPCs is similar to that of the first embodiment. Moreover, a first branch portion, a first-branch-portion forming portion, a first FPC portion, a second branch portion, a second-branch-portion forming portion, and a second FPC portion are also similar to those of the first embodiment.

As described above, the FPC 100B according to the present embodiment includes the first FPC portion to which a connector 20 is connected and the second FPC portion provided through the branch portion 112B branched from the first FPC portion. Moreover, in the present embodiment, the branch portion 112B is bent to form a step between the first FPC portion and the second FPC portion, so that the first FPC portion is arranged on one surface side of a cell 10 and the second FPC portion is arranged on an other surface side of the cell 10 (see FIGS. 8A and 8B). Note that FIG. 7A shows the state before the branch portion 112B is bent, and FIG. 7B shows the state after the branch portion 112B has been bent. As shown in FIG. 7B, in the present embodiment, it is configured such that the first FPC portion and the second FPC portion overlap with each other by bending of the branch portion 112B. The FPC 100B is arranged on the cell 10 with the cell 10 sandwiched between the first FPC portion and the second FPC portion.

The first FPC portion is provided with a temperature measurement element (first temperature measurement element) S that measures the temperature of one surface of the cell 10, and the second FPC portion is provided with a temperature measurement element (second temperature measurement element) S that measures the temperature of an other surface of the cell 10. In the present embodiment, the temperature measurement elements S are provided at two locations for each of the end-side FPCs 131, 132, but the number of temperature measurement elements S and arrangement thereof can be set as necessary according to, e.g., the dimensions and shape of the cell 10 and use environment thereof. Moreover, in the present embodiment, it is also configured such that the temperature measurement element S that measures the temperature of the other surface of the cell 10 is arranged at a position immediately in the back of each temperature measurement element S that measures the temperature of the one surface of the cell 10.

As described above, in the present embodiment, the branch portion 112B is bent to form a step between the first FPC portion and the second FPC portion, so that the first temperature measurement element is arranged on the one surface side of the cell 10 and the second temperature measurement element is arranged on the other surface side of the cell 10.

In the FPC 100B of the present embodiment configured as described above, advantageous effects similar to those of the first embodiment can also be obtained. Moreover, as compared to a case of folding the branch portion as in the first embodiment, there are advantages that the first FPC portion and the second FPC portion are less likely to be lifted from the cell 10 and can easily closely contact the cell 10. Note that the present embodiment has also described the configuration in which the branch portion 112B is provided at only one location, but for example, a branch portion such as a branch portion 112SB indicated by a dashed line in FIG. 7A is further provided so that a configuration in which a plurality of branch portions is provided can be employed.

### Fourth Embodiment

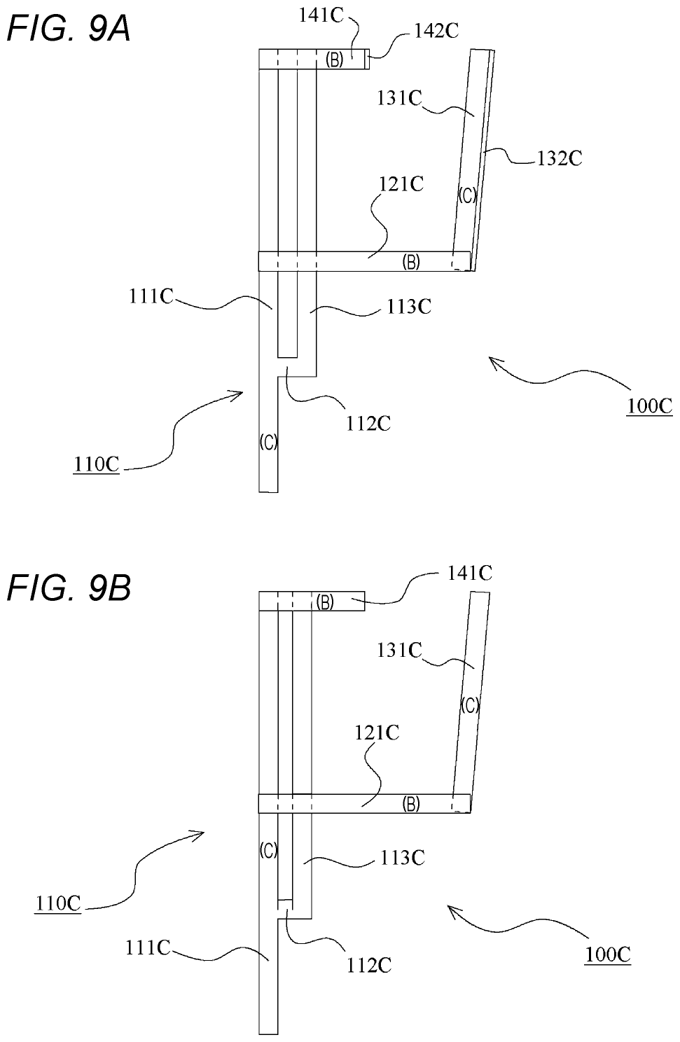

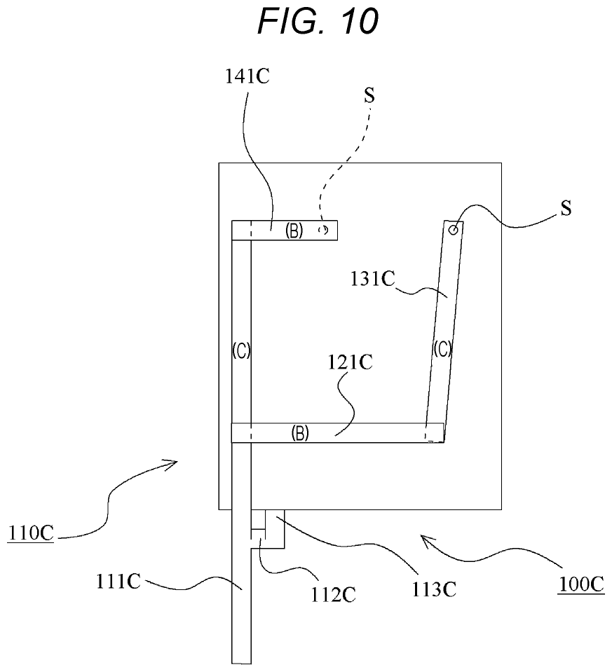

FIGS. 9A, 9B, and 10 show a fourth embodiment of the present invention. FIGS. 9A and 9B are plan views of an FPC according to a fourth embodiment of the present invention, FIG. 9A showing a state before bending of a branch portion and FIG. 9B showing a state after bending of the branch portion. FIG. 10 is schematic view of the configuration of the FPC according to the fourth embodiment of the present invention in a state of the FPC being placed on a cell. The branch portion is folded 180° in the above-described second embodiment, and on the other hand, the present embodiment is different in that the branch portion is bent. A basic configuration of each member is the same as that of the second embodiment.

As in the first embodiment, an FPC 100C according to the present embodiment is also formed in such a manner that a plurality of FPCs is joined to each other, and each of the plurality of FPCs is a so-called single-sided FPC. For the sake of convenience in FIGS. 9A, 9B, and 10, (B) is assigned in a case where a base film is shown on the front side of the figures, and (C) is assigned in a case where a cover film is shown on the front side of the figures.

A battery to which the FPC 100C according to the present embodiment is applied is similar to that of the first embodiment, and therefore, description thereof will be omitted.

The FPC 100C according to the present embodiment includes a connector-side FPC 110C, two linear intermediate FPCs (in each figure, only one intermediate FPC 121C is shown), and four linear end-side FPCs 131C, 132C, 141C, 142C.

The connector-side FPC 110C has a linear first body portion 111C, a linear second body portion 113C, and a branch portion 112C connecting the first body portion 111C and the second body portion 113C to each other. It can be said that the second body portion 113C is provided through the branch portion 112C branched from the first body portion 111C.

Joint between the FPCs is similar to that of the second embodiment. Moreover, a first branch portion, a first-branch-portion forming portion, a first FPC portion, a second branch portion, a second-branch-portion forming portion, and a second FPC portion are also similar to those of the second embodiment.

As described above, the FPC 100C according to the present embodiment includes the first FPC portion to which a connector 20 is connected and the second FPC portion provided through the branch portion 112C branched from the first FPC portion. Moreover, in the present embodiment, the branch portion 112C is bent to form a step between the first FPC portion and the second FPC portion, so that the first FPC portion is arranged on one surface side of a cell 10 and the second FPC portion is arranged on an other surface side of the cell 10. Note that FIG. 9A shows the state before the branch portion 112C is bent, and FIG. 9B shows the state after the branch portion 112C has been bent. As shown in FIG. 9B, in the present embodiment, it is configured such that the first FPC portion and the second FPC portion overlap with each other by bending of the branch portion 112C. The FPC 100C is arranged on the cell 10 with the cell 10 sandwiched between the first FPC portion and the second FPC portion.

The first FPC portion is provided with a temperature measurement element (first temperature measurement element) S that measures the temperature of one surface of the cell 10, and the second FPC portion is provided with a temperature measurement element (second temperature measurement element) S that measures the temperature of the other surface of the cell 10. In the present embodiment, the temperature measurement element S is provided at one location for each of the end-side FPCs 131C, 141C, 132C, 142C, but the number of temperature measurement elements S and arrangement thereof can be set as necessary according to, e.g., the dimensions and shape of the cell 10 and use environment thereof. Moreover, in the present embodiment, it is also configured such that the temperature measurement element S that measures the temperature of the other surface of the cell 10 is arranged at a position immediately in the back of each temperature measurement element S that measures the temperature of the one surface of the cell 10.

As described above, in the present embodiment, the branch portion 112C is bent to form the step between the first FPC portion and the second FPC portion, so that the first temperature measurement element is arranged on the one surface side of the cell 10 and the second temperature measurement element is arranged on the other surface side of the cell 10.

In the FPC 100C of the present embodiment configured as described above, advantageous effects similar to those of the first embodiment can be obtained.

### Fifth Embodiment

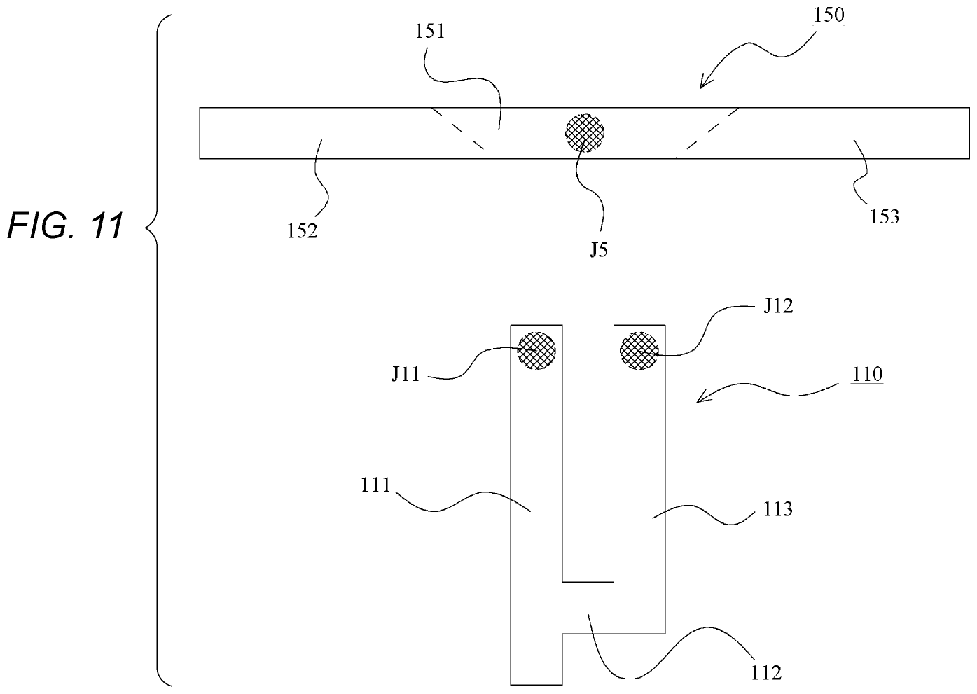

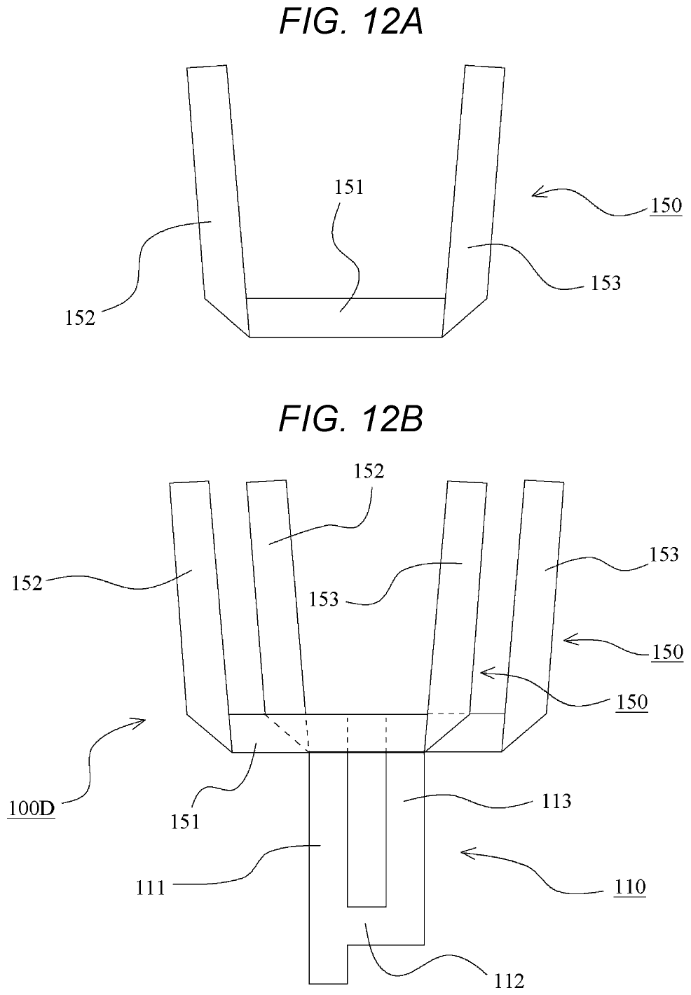

FIGS. 11, 12A, and 12B show a fifth embodiment of the present invention. FIG. 11 is an exploded view of components of an FPC according to the fifth embodiment of the present invention. FIGS. 12A and 12B are views for describing the FPC according to the fifth embodiment of the present invention, FIG. 12A being a plan view in a state of one component being folded and FIG. 12B being a plan view of the FPC according to the present embodiment. The present embodiment is different from the first embodiment in that the intermediate FPC and the two end-side FPCs joined to the intermediate FPC in the above-described first embodiment are formed as one linear FPC. The other configurations are the same as those of the first embodiment, and therefore, the same reference numerals are used to represent the same components as those of the first embodiment and description thereof will be omitted as necessary.

An FPC 100D according to the present embodiment is also formed in such a manner that a plurality of FPCs is joined to each other, and each of the plurality of FPCs is a so-called single-sided FPC. A battery to which the FPC 100D according to the present embodiment is applied is similar to that of the first embodiment, and therefore, description thereof will be omitted.

The FPC 100D according to the present embodiment includes a connector-side FPC 110 and two linear branch FPCs 150. Note that in FIG. 11, only one branch FPC 150 is shown.

The connector-side FPC 110 is as described in the first embodiment. In the present embodiment, the linear branch FPC 150 is folded at two dashed lines in FIG. 11, so that a portion 151 equivalent to the intermediate FPC in the first embodiment and portions 152, 153 equivalent to the end-side FPCs are provided. The back side of the vicinity of regions J5 of the two branch FPCs folded in this manner is joined to the vicinities of a region J11 and a region J12 of the connector-side FPC 110. In this manner, the FPC 100D having a configuration similar to that of the first embodiment is obtained.

In the present embodiment, the branch FPC 150 joined to a first body portion 111 is a first branch portion, and is a first-branch-portion forming portion. Moreover, the first body portion 111 and the branch FPC 150 joined to the first body portion 111 form a first FPC portion. The branch FPC 150 joined to a second body portion 113 is a second branch portion, and is a second-branch-portion forming portion. Moreover, the second body portion 113 and the branch FPC 150 joined to the second body portion 113 form a second FPC portion. A temperature measurement element S is as described in the first embodiment, and therefore, description thereof will be omitted.

In the FPC 100D of the present embodiment configured as described above, advantageous effects similar to those of the first embodiment can also be obtained. Moreover, in the present embodiment, locations at which the FPCs are joined to each other are reduced, and therefore, less countermeasures are taken for, e.g., strength and waterproof properties. Note that in the present embodiment, a branch portion 112 is folded 180° as in the first embodiment, but a configuration in which a step is formed between the first FPC portion and the second FPC portion by bending of the branch portion as in the third embodiment can be employed.

Note that in each of the above-described embodiments, the configuration has been described, in which the FPCs arranged on both surfaces of the cell overlap with each other and the temperature measurement element on the other surface side is arranged immediately in the back of the temperature measurement element on the one surface side. In a case of a large cell, it is assumed that temperature distribution is not similar between both sides, and for this reason, in a case of measuring temperatures at the same position between both sides, the above-described configuration is preferably employed. Note that according to, e.g., use conditions, the positions of the temperature measurement elements on both sides may be different from each other in a case of measuring temperatures at different positions between both sides of the cell. Needless to say, the shapes of the FPCs on both sides may be differentiated such that the FPCs on both sides do not overlap with each other. Even in a case of employing this configuration, position accuracy in a temperature measurement element arrangement relationship between both sides can also be enhanced, needless to say.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A battery comprising:
a cell; and
a flexible printed circuit board to which a temperature measurement element that measures a temperature of the cell is connected,
wherein the flexible printed circuit board includes
a first flexible printed circuit board portion to which a connector is connected, and
a second flexible printed circuit board portion provided through a branch portion branched from the first flexible printed circuit board portion,
the first flexible printed circuit board portion is provided with a first temperature measurement element arranged on one surface side of the cell to measure a temperature of one surface of the cell, and
the second flexible printed circuit board portion is provided with a second temperature measurement element arranged on an other surface side of the cell to measure a temperature of an other surface of the cell.

2. The battery according to claim 1, wherein
the first flexible printed circuit board portion has a linear first body portion, and the second flexible printed circuit board portion has a linear second body portion,
the first body portion and the second body portion are connected to each other through the branch portion, and
the branch portion is folded 180°, so that the first temperature measurement element is arranged on the one surface side of the cell and the second temperature measurement element is arranged on the other surface side of the cell.

3. The battery according to claim 1, wherein
the first flexible printed circuit board portion has a linear first body portion, and the second flexible printed circuit board portion has a linear second body portion,
the first body portion and the second body portion are connected to each other through the branch portion, and
the branch portion is bent to form a step between the first flexible printed circuit board portion and the second flexible printed circuit board portion, so that the first temperature measurement element is arranged on the one surface side of the cell and the second temperature measurement element is arranged on the other surface side of the cell.

4. The battery according to claim 2, wherein
the first flexible printed circuit board portion has a first branch portion branched from the first body portion and joined to the first body portion, and
the second flexible printed circuit board portion has a second branch portion branched from the second body portion and joined to the second body portion.

5. The battery according to claim 4, wherein
the first branch portion includes a plurality of linear first-branch-portion forming portions, and the second branch portion includes a plurality of linear second-branch-portion forming portions.

6. The battery according to claim 4, wherein
the first branch portion includes a single linear first-branch-portion forming portion, and the first-branch-portion forming portion is arranged with folded 180° at least at one location, and
the second branch portion includes a single linear second-branch-portion forming portion, and the second-branch-portion forming portion is arranged with folded 180° at least at one location.

7. The battery according to claim 4, wherein
electric lines three-dimensionally intersect with each other while keeping insulation from each other at least at a joint portion between the first body portion and the first branch portion and a joint portion between the second body portion and the second branch portion, so that a first ground line for the first temperature measurement element and a second ground line for the second temperature measurement element are joined into one ground line at least at a portion of the first flexible printed circuit board portion connected to the connector.

8. A flexible printed circuit board to which a temperature measurement element that measures a temperature of a cell forming a battery is connected, comprising:
a first flexible printed circuit board portion to which a connector is connected; and
a second flexible printed circuit board portion provided through a branch portion branched from the first flexible printed circuit board portion,
wherein the first flexible printed circuit board portion is provided with a first temperature measurement element arranged on one surface side of the cell to measure a temperature of one surface of the cell, and
the second flexible printed circuit board portion is provided with a second temperature measurement element arranged on an other surface side of the cell to measure a temperature of an other surface of the cell.

9. The flexible printed circuit board according to claim 8, wherein
the first flexible printed circuit board portion has a linear first body portion, and the second flexible printed circuit board portion has a linear second body portion,
the first body portion and the second body portion are connected to each other through the branch portion, and
the branch portion is folded 180°, so that the first temperature measurement element is arranged on the one surface side of the cell and the second temperature measurement element is arranged on the other surface side of the cell.

10. The flexible printed circuit board according to claim 8, wherein
the first flexible printed circuit board portion has a linear first body portion, and the second flexible printed circuit board portion has a linear second body portion,
the first body portion and the second body portion are connected to each other through the branch portion, and
the branch portion is bent to form a step between the first flexible printed circuit board portion and the second flexible printed circuit board portion, so that the first temperature measurement element is arranged on the one surface side of the cell and the second temperature measurement element is arranged on the other surface side of the cell.

11. The flexible printed circuit board according to claim 9, wherein
the first flexible printed circuit board portion has a first branch portion branched from the first body portion and joined to the first body portion, and
the second flexible printed circuit board portion has a second branch portion branched from the second body portion and joined to the second body portion.

12. The flexible printed circuit board according to claim 11, wherein
the first branch portion includes a plurality of linear first-branch-portion forming portions, and the second branch portion includes a plurality of linear second-branch-portion forming portions.

13. The flexible printed circuit board according to claim 11, wherein
the first branch portion includes a single linear first-branch-portion forming portion, and the first-branch-portion forming portion is arranged with folded 180° at least at one location, and
the second branch portion includes a single linear second-branch-portion forming portion, and the second-branch-portion forming portion is arranged with folded 180° at least at one location.

14. The flexible printed circuit board according to claim 11, wherein
electric lines three-dimensionally intersect with each other while keeping insulation from each other at least at a joint portion between the first body portion and the first branch portion and a joint portion between the second body portion and the second branch portion, so that a first ground line for the first temperature measurement element and a second ground line for the second temperature measurement element are joined into one ground line at least at a portion of the first flexible printed circuit board portion connected to the connector.
